(19) United States
(12) Patent Application Publication
(10) Pub. No.: US 2026/0143920 A1
(43) Pub. Date: May 21, 2026

(54) ORGANIC LIGHT EMITTING ELEMENT AND MANUFACTURING METHOD THEREOF

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); KUO-CHENG HSU, TAICHUNG CITY (TW); YICHANG WANG, ZHEJIANG PROVINCE (CN)

(21) Appl. No.: 19/370,795

(22) Filed: Oct. 28, 2025

Related U.S. Application Data
(60) Provisional application No. 63/722,081, filed on Nov. 19, 2024.

(30) Foreign Application Priority Data
Nov. 15, 2024 (CN) 202411640509.2
Aug. 29, 2025 (CN) 202511235601.5

(51) Int. Cl. H10K 59/122; H10K 59/12

(52) U.S. Cl. CPC H10K 59/122; H10K 59/1201

(57) ABSTRACT

An organic light emitting element includes a substrate, a first organic light emitting unit and a second organic light emitting unit. The first organic light emitting unit is located over the substrate, and includes a first electrode and a first organic light emitting layer located over the first electrode. The second organic light emitting unit is adjacent to the first organic light emitting layer, and includes a second electrode and a second organic light emitting layer located over the second electrode. The first organic light emitting layer and the second organic light emitting layer overlap vertically.

### PRIORITY CLAIM AND CROSS-REFERENCE

This application claims the benefit of U.S. Provisional Application No. 63/722,081, filed on November 19, 2024, and claims priority to China Patent Application Serial No. 202411640509.2, filed on November 15, 2024, and China Patent Application Serial No. 202511235601.5, filed on August 29, 2025, the entirety of which are incorporated by reference herein.

### BACKGROUND OF THE DISCLOSURE

### FIELD OF THE DISCLOSURE

The present disclosure relates to an organic light emitting element, and more particularly to an organic light emitting element including an organic light-emitting diode (OLED) structure.

### DESCRIPTION OF THE PRIOR ART

Currently, a fine metal mask (FMM) is commonly used in a coating step for a light emitting layer of an organic light emitting element, or white light in combination with a color film are used for a manufacturing process. However, fineness or resolution of pixels resulted from the manufacturing process above is rather poor.

### SUMMARY OF THE DISCLOSURE

In the present disclosure, an organic light emitting element includes a substrate, a first organic light emitting unit and a second organic light emitting unit. The first organic light emitting unit is located over the substrate, and includes a first electrode and a first organic light emitting layer located over the first electrode. The second organic light emitting unit is adjacent to the first organic light emitting layer, and includes a second electrode and a second organic light emitting layer located over the second electrode. The first organic light emitting layer and the second organic light emitting layer overlap vertically.

In the present disclosure, a manufacturing method of an organic light emitting element includes: disposing a first electrode over a substrate; forming a plurality of protrusions having a spacing and on two sides of the first electrode; sequentially forming a sacrifice layer and a photoresist over the first electrode; forming an opening passing through the sacrifice layer and the photoresist directly above the first electrode, wherein the opening in the sacrifice layer has a first width and in the photoresist has a second width, the first width is greater than the second width and the second width is greater than the spacing; forming the first organic light emitting layer over the first electrode; and removing the sacrifice layer and the photoresist.

In some embodiments, the organic light emitting element further includes a protrusion located between the first organic light emitting unit and the second organic light emitting unit, wherein the first organic light emitting layer and the second organic light emitting layer extend over a top of the protrusion.

In some embodiments, the first organic light emitting layer and the second organic light emitting layer overlap vertically over the top of the protrusion.

In some embodiments, a thickness of the first organic light emitting layer on a sidewall of the protrusion is greater than a thickness of the first organic light emitting layer on the top of the protrusion.

In some embodiments, the first organic light emitting unit and the second organic light emitting unit emit lights having different wavelengths.

In some embodiments, the first organic light emitting layer includes a first organic emissive layer, a first electron transport layer and a first electron injection layer, and the second organic light emitting layer includes a second organic emissive layer, a second electron transport layer and a second electron injection layer, wherein the second organic emissive layer, the second electron transport layer and the second electron injection layer extend over the first organic emissive layer, the first electron transport layer and the first electron injection layer.

In some embodiments, the first organic light emitting layer extends above a sidewall of the second electrode.

In some embodiments, the organic light emitting element further includes a third organic light emitting unit, which is adjacent to the second organic light emitting layer and includes a third electrode and a third organic light emitting layer located over the third electrode, wherein the third organic light emitting layer and the second organic light emitting layer overlap vertically.

In some embodiments, the opening in the sacrifice layer has an undercut located directly above the protrusion.

In some embodiments, a depth of the undercut is 0.5 μm to 2 μm.

In some embodiments, a difference between the second width and the spacing is greater than or equal to 1 μm.

In some embodiments, the second width is 4 μm to 10 μm, and the spacing is 3 μm to 9 μm.

In some embodiments, after the opening is formed, an inclination angle of the photoresist is 50° to 90°.

In some embodiments, the first organic light emitting layer is formed by means of evaporation, and an incident angle of the evaporation is 40° to 90°.

In some embodiments, a thickness of the sacrifice layer is 0.5 μm to 1 μm, a thickness of the photoresist is 1 μm to 2 μm, and a thickness of the first organic light emitting layer is 200 Å to 1300 Å.

In some embodiments, the manufacturing method of an organic light emitting layer further includes: disposing a second electrode adjacent to the first electrode, wherein the sacrifice layer and the photoresist cover the second electrode while forming the first organic light emitting layer; and after the sacrifice layer and the photoresist are removed, forming a second organic light emitting layer over the second electrode, the protrusion and the first organic light emitting layer.

In some embodiments, the opening has a T-shaped structure.

In some embodiments, the opening has an arc-shaped sidewall in the sacrifice layer and a sloped sidewall in the photoresist.

In some embodiments, the spacing defines a light emitting region of the first organic light emitting layer, and two sides of the light emitting region are separated by different distances from edges of the opening.

### BRIEF DESCRIPTION OF THE DRAWINGS

To assist a reader in achieving optimal understanding, it is suggested that the accompanying drawings and the detailed description thereof be referred to while reading the present disclosure. It should be noted that various features are not drawn to scale, as a common standard practice in industry. In fact, for clear illustrations, dimensions of the various features may be intentionally enlarged or reduced.

FIG. 1A to FIG. 1J depict a manufacturing method of an organic light emitting element according to some embodiments;

FIG. 2 is a cross-sectional diagram of an intermediate structure of a manufacturing method of an organic light emitting element according to some embodiments;

FIG. 3A is a top view of an intermediate structure of a manufacturing method of an organic light emitting element according to some embodiments;

FIG. 3B is a top view of an intermediate structure of a manufacturing method of an organic light emitting element according to some embodiments;

FIG. 4A is a top view of an intermediate structure of a manufacturing method of an organic light emitting element according to some embodiments;

FIG. 4B is a top view of an intermediate structure of a manufacturing method of an organic light emitting element according to some embodiments;

FIG. 5 is a cross-sectional diagram of an organic light emitting element;

FIG. 6 is a cross-sectional diagram of an organic light emitting element; and

FIG. 7 is a cross-sectional diagram of an organic light emitting element.

### DETAILED DESCRIPTION OF THE EMBODIMENTS

Numerous different embodiments or examples are provided in the present disclosure below to implement different features of the present application. Specific examples of components and configurations are described as below with the aim of simplifying the disclosure of the present application. However, these examples are merely illustrations and are not to be construed as limitations to the present application.

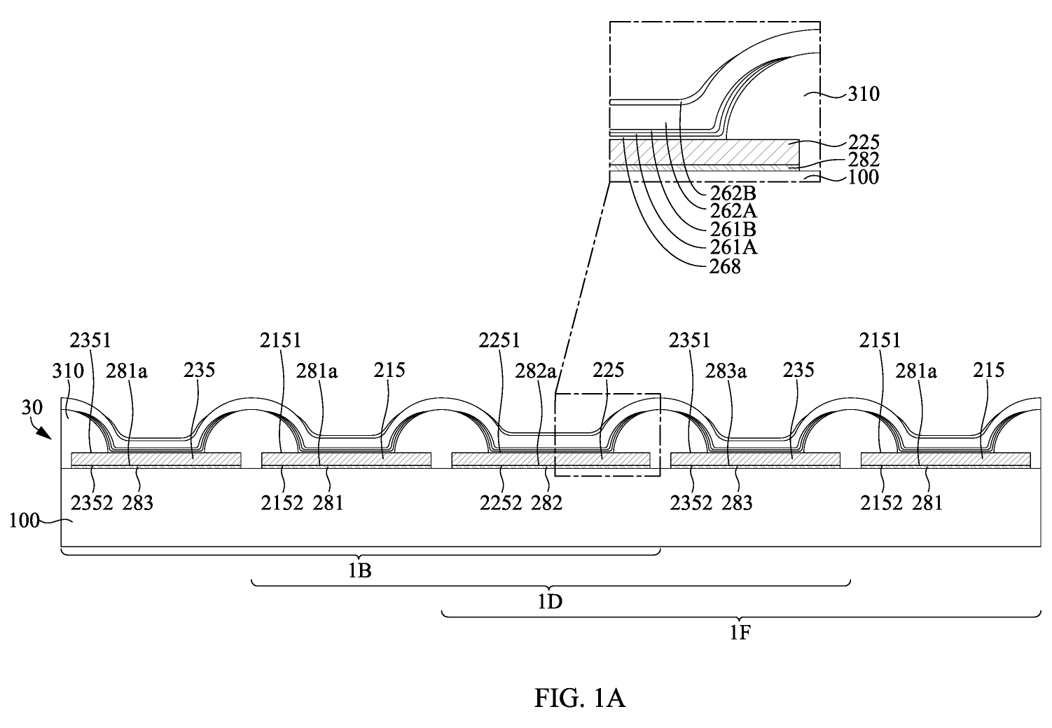

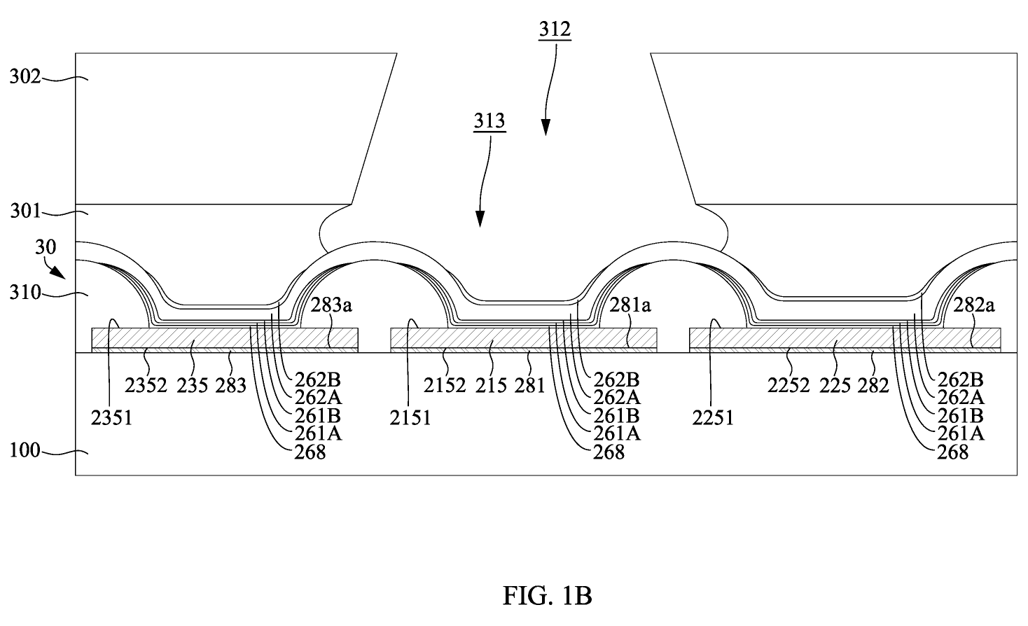

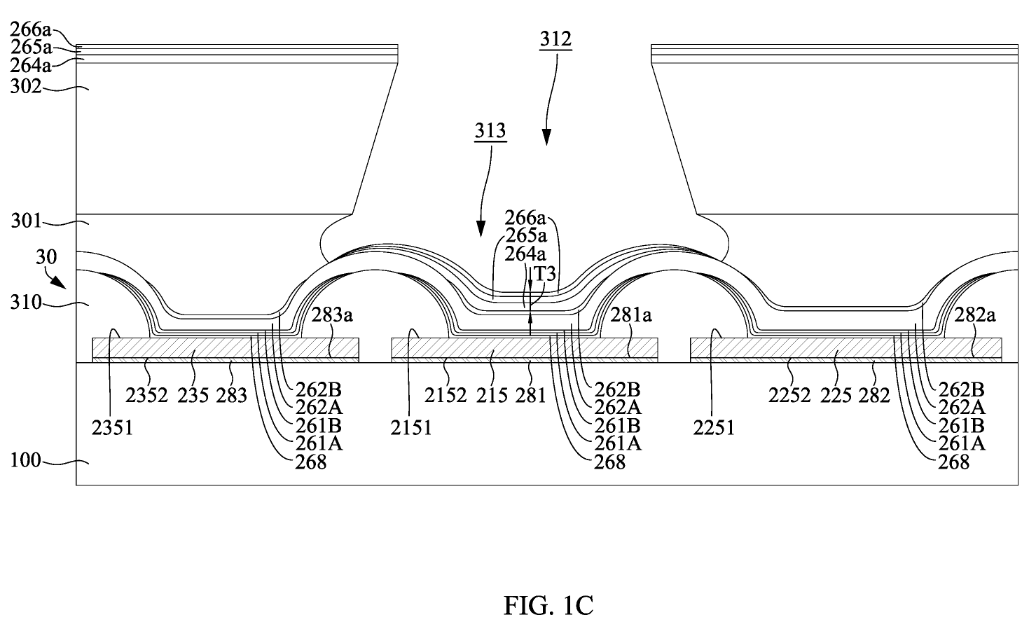

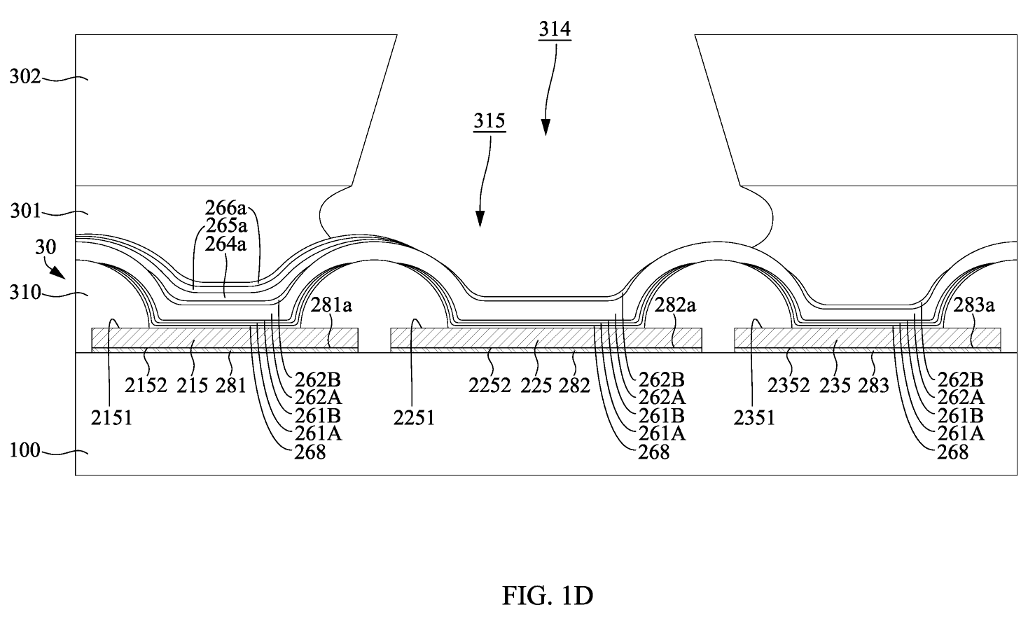

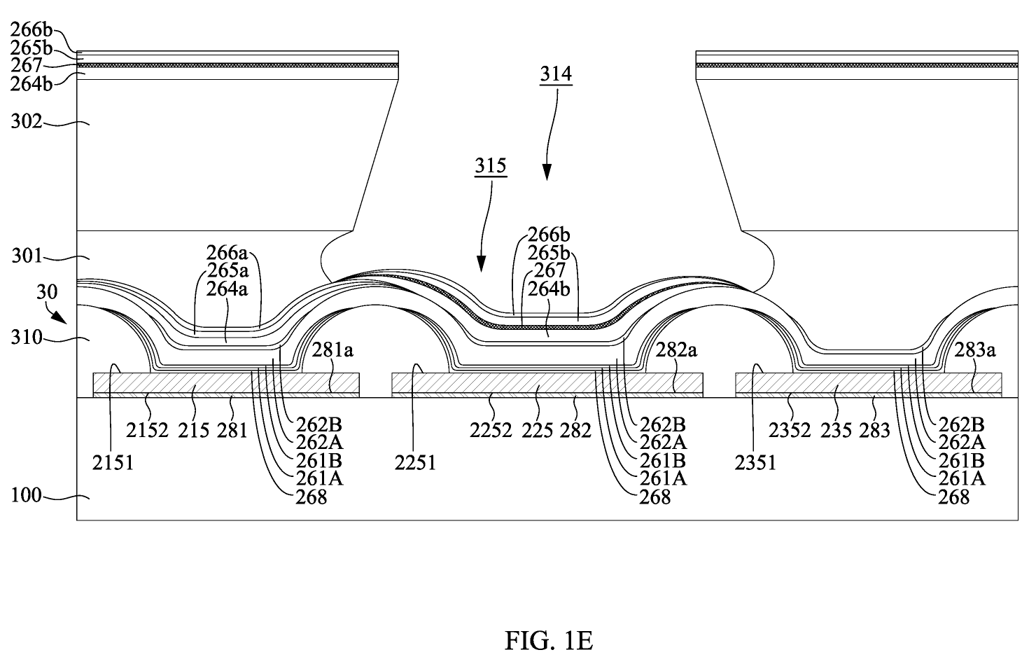

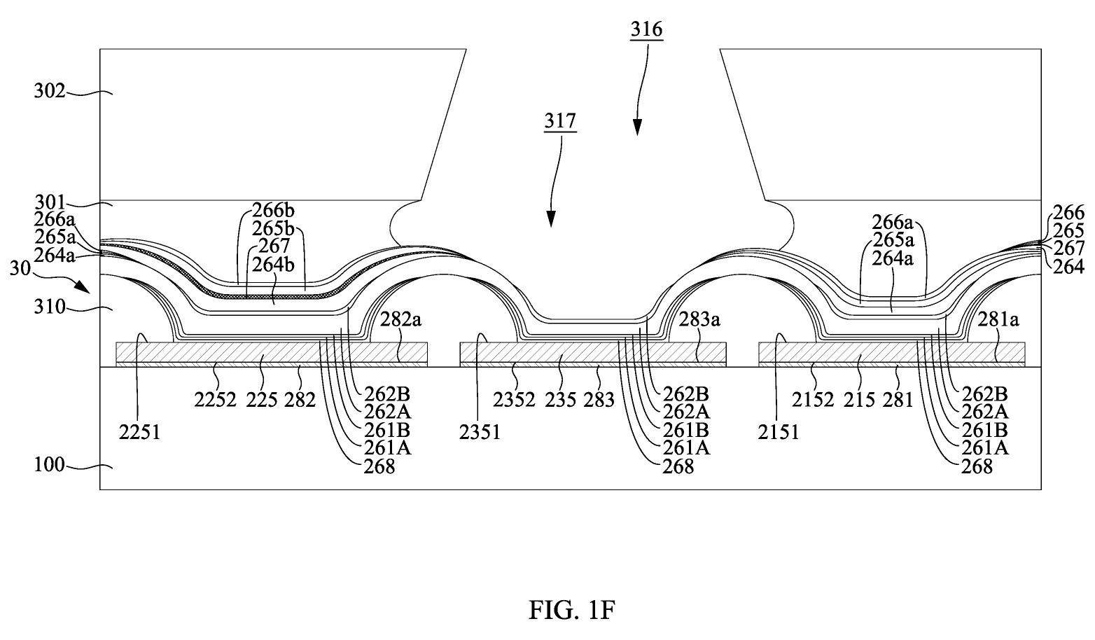

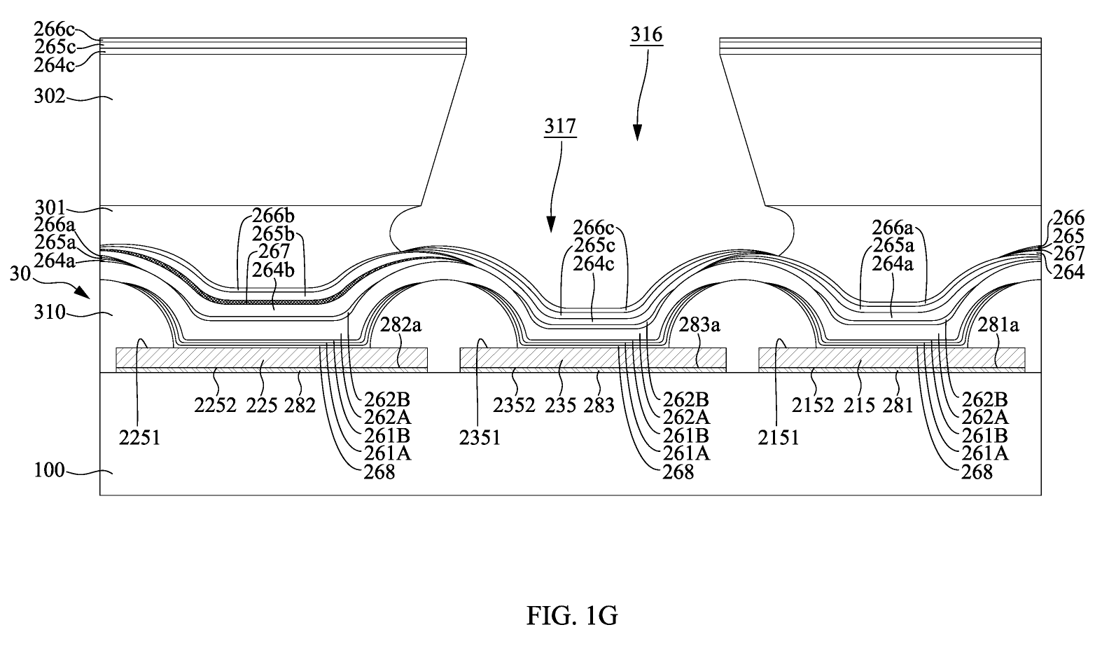

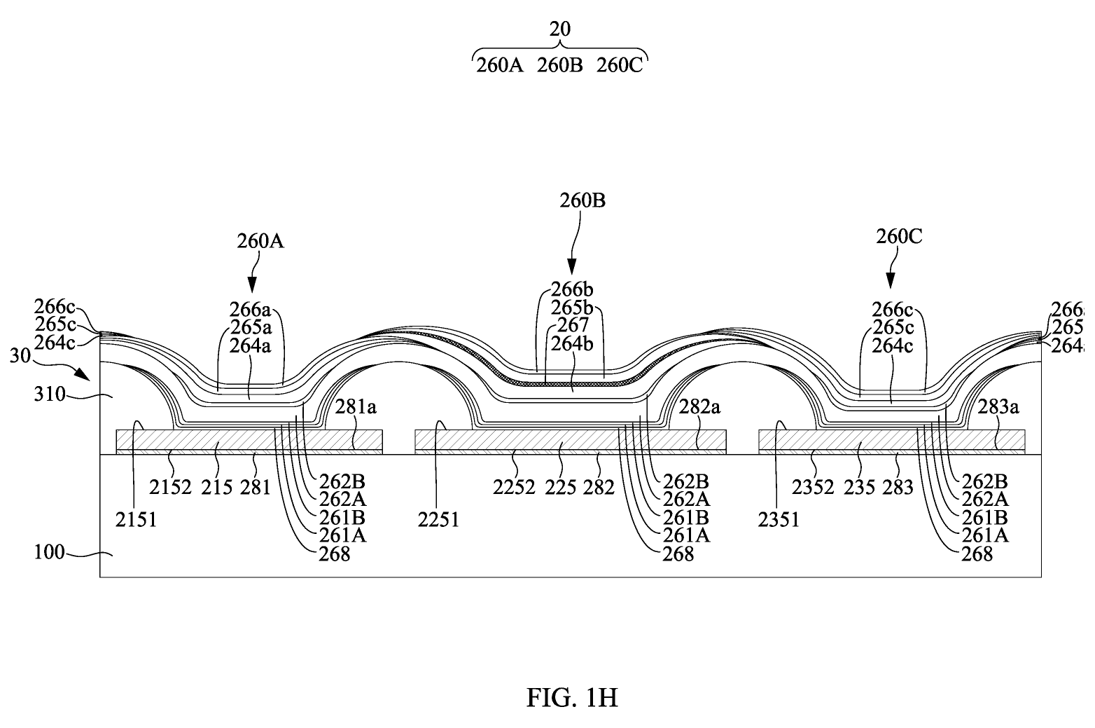

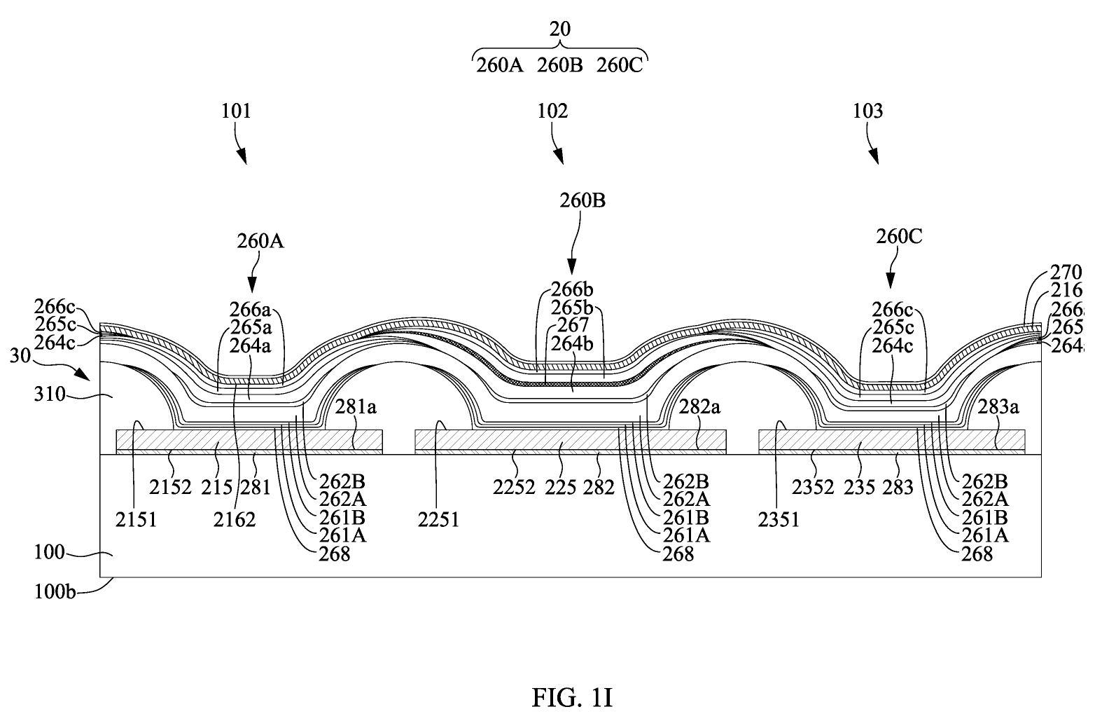

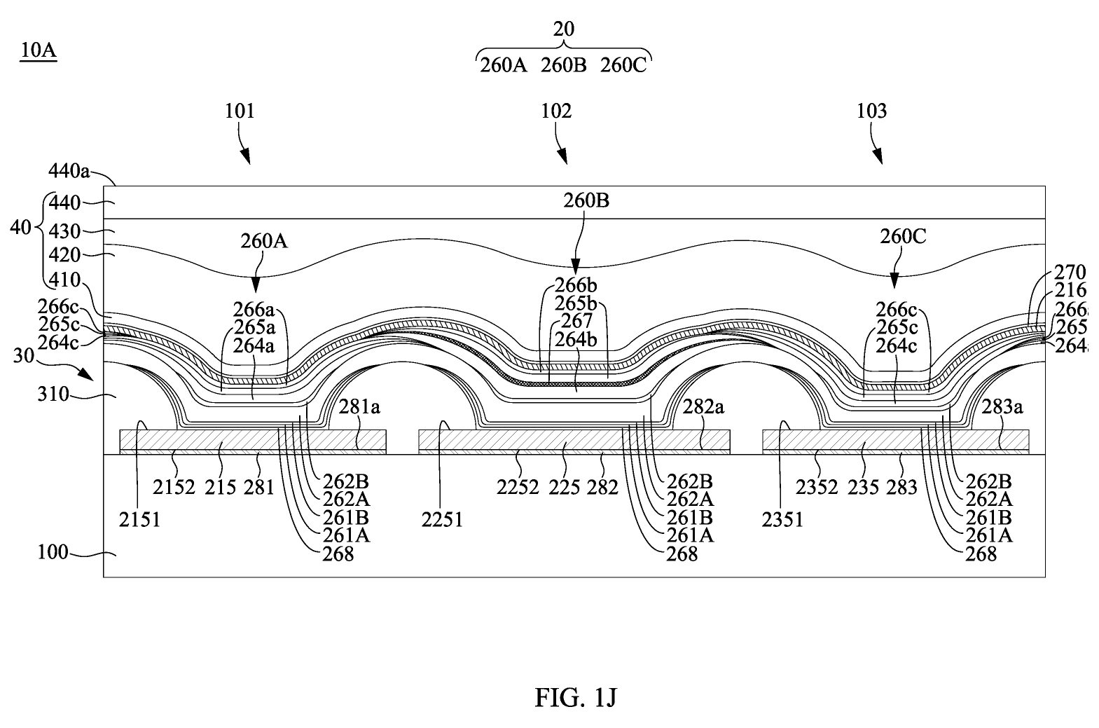

FIG. 1A to FIG. 1J depict a manufacturing method of an organic light emitting element 10A according to some embodiments. The organic light emitting element 10A is, for example, a light emitting element including an organic light-emitting diode (OLED) structure.

As shown in FIG. 1A, in some embodiments, a substrate 100 is provided. The substrate 100 may include a region 1B, a region 1D and a region 1F, which are respectively further described with the accompanying drawings below. The substrate 100 may include a transistor array, which is configured to correspond to light emitting pixels in a light emitting layer. The substrate 100 may include a plurality of capacitors. In some embodiments, more than one transistor is configured with one capacitor and one light emitting pixel to form a circuit. In some embodiments, the substrate 100 may include glass.

In some embodiments, a plurality of reflective layers 281, 282 and 283 are arranged over the substrate 100. A plurality of electrodes 215, 225 and 235 are arranged over the reflective layers 281, 282 and 283. The electrode 215 may have surfaces 2151 and 2152, the electrode 225 may have surfaces 2251 and 2252, and the electrode 235 may have surfaces 2351 and 2352. In some embodiments, the reflective layer 281 is located between the substrate 100 and the electrode 215. In some embodiments, the reflective layer 282 is located between the substrate 100 and the electrode 225. In some embodiments, the reflective layer 283 is located between the substrate 100 and the electrode 235. In other words, the reflective surfaces (reflective surfaces 281a, 282a and 283a of the reflective layers 281, 282 and 283) are formed on lower surfaces (the surfaces 2152, 2252 and 2352) of the electrodes 215, 225 and 235.

In some embodiments, each of the reflective layers 281, 282 and 283 includes a reflective metal or a non-conductive reflective material. In some embodiments, each of the reflective layers 281, 282 and 283 includes silver, a distributed Bragg reflector (DBR) or other appropriate reflective materials. In some embodiments, the reflectance of a reflective metal gets higher as a thickness of the reflective metal increases. In some embodiments, the reflectance of a DBR gets higher as the number of layers in the DBR increases.

In some embodiments, the electrode 215, 225 and 235 are anodes. In some embodiments, the electrodes 215, 225 and 235 include a metal material, for example, Ag, Al, Mg, Au, AlCu alloy or AgMo alloy. In some embodiments, the electrodes 215, 225 and 235 include indium tin oxide (ITO), indium zinc oxide (IZO) or other appropriate materials. In some embodiments, the electrodes 215, 225 and 235 are made of a transparent conductive material.

In some embodiments, a spacer structure 30 is formed over the substrate 100 and partially covers the electrodes 215, 225 and 235. The spacer structure 30 may provide a recess array used to accommodate a light emitting pixel array. In some embodiments, the spacer structure 30 serves as a pixel defined layer (PDL). In some embodiments, the spacer structure 30 includes a photosensitive material.

In some embodiments, the spacer structure 30 includes a plurality of protrusions 310. In some embodiments, the protrusions 310 define a pixel region. When viewing the cross-sectional diagram shown in FIG. 1A, a person skilled in the art would be able to understand that the protrusions 310 are depicted in a disconnected manner. However, when viewing the schematic top view, the protrusions 310 may be connected to one another by other parts of the spacer structure 30.

In some embodiments, each protrusion 310 fills a gap between the adjacent electrodes 215, 225 and 235, and a gap between adjacent reflective layers 281, 282 and 283. Each of the electrodes 215, 225 and 235 is partially covered by the protrusion 310. In some embodiments, the pattern of the spacer structure 30 is designed according to a pixel layout. In some embodiments, the spacer structure 30 serves as a pixel defined layer. In some embodiments, the protrusions 310 define a pixel region.

In some embodiments, the spacer structure 30 includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a blackbody material, which has an absorption rate of greater than or equal to 90%, 95%, 99%, 99.5% or 99.9% for visible light.

In some embodiments, the spacer structure 30 has an absorption rate of greater than or equal to 50% for a specific wavelength. In some embodiments, the spacer structure 30 has an absorption rate of greater than or equal to 60% for a specific wavelength. In some embodiments, the spacer structure 30 has an absorption rate of greater than or equal to 70% for a specific wavelength. In some embodiments, the spacer structure 30 has an absorption rate of greater than or equal to 80% for a specific wavelength. In some embodiments, the spacer structure 30 has an absorption rate of greater than or equal to 90% for a specific wavelength. In some embodiments, the spacer structure 30 has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

Next, in some embodiments, an inorganic barrier layer 268, a hole injection layer (HIL) 261A, a hole injection layer (HIL) 261B, a hole transport layer (HTL) 262A and a hole transport layer (HTL) 262B are arranged over surfaces of the protrusions 310 and the electrodes 215, 225 and 235.

In some embodiments, the inorganic barrier layer 268, the hole injection layer 261A, the hole injection layer 261B, the hole transport layer 262A and the hole transport layer 262B are formed by means of evaporation. In some embodiments, the inorganic barrier layer 268, the hole injection layer 261A, the hole injection layer 261B, the hole transport layer 262A and the hole transport layer 262B may completely undergo the evaporation above the electrodes 215, 225 and 235. Due to smaller thicknesses of the inorganic barrier layer 268, the hole injection layer 261A, the hole injection layer 261B and the hole transport layer 262B, these layers above each of the electrodes 215, 225 and 235 are disconnected from one another via the protrusions 310. Due to a greater thickness of the hole transport layer 262A, the hole transport layer 262A is formed to continuously extend over the electrodes 215, 225 and 235 and the protrusions 310.

In some embodiments, a side surface of the inorganic barrier layer 268 is in contact with the protrusion 310. In some embodiments, the inorganic barrier layer 268 includes a transition metal oxide. In some embodiments, the inorganic barrier layer 268 includes molybdenum oxide (MoO₃). In some embodiments, a thickness of the inorganic barrier layer 268 is less than or equal to 100 Å. In some embodiments, a ratio of the thickness of the inorganic barrier layer 268 to the thicknesses of the electrodes 215, 225 and 235 is less than 0.1, 0.06 or 0.03. In some embodiments, the inorganic barrier layer 268 and the hole injection layers 261A and 261B may jointly form a hole injection layer.

Next, refer to FIG. 1B. FIG. 1B shows an enlarged view of the region 1B (FIG. 1A). In some embodiments, a sacrifice layer 301 is arranged over the protrusion 310, and the sacrifice layer 301 also covers the inorganic barrier layer 268, the hole injection layer 261A, the hole injection layer 261B, the hole transport layer 262A, the hole transport layer 262B, and the electrodes 215, 225 and 235. Next, in some embodiments, a photosensitive 302 is arranged over the sacrifice layer 301. In some embodiments, the sacrifice layer 301 and the photoresist 302 are formed by means of coating, and an opening 312 is formed in the photoresist 302 and an opening 313 is formed in the sacrifice layer 301 by means of etching. The openings 312 and 313 are located directly above the electrode 215, and expose the hole transport layer 262B over the electrode 215.

In some embodiments, predetermined evaporation positions of an organic emissive layer (EML) 264a, an electron transport layer (ETL) 265a and an electron injection layer (EIL) 266a (as shown in FIG. 1C) are defined by using the sacrifice layer 301 and the photoresist 302 as a patterning mask layer.

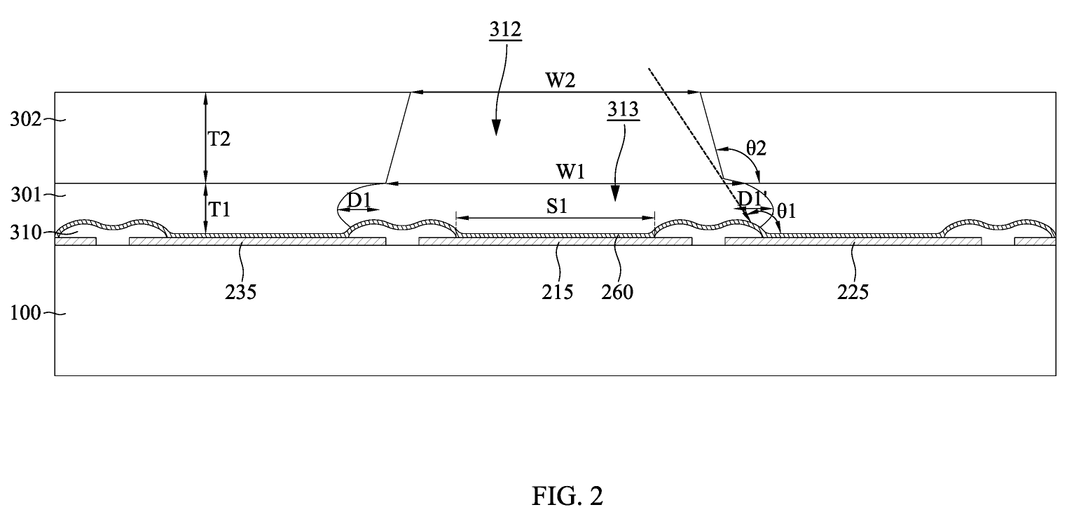

Refer to FIG. 2 for further details of FIG. 1B in the description below. FIG. 2 shows a cross-sectional diagram of an intermediate structure of a manufacturing method of the organic light emitting element 10A according to some embodiments. As shown in FIG. 2, in some embodiments, a thickness T1 of the sacrifice layer 301 is 0.5 μm to 1 μm, and a thickness T2 of the photoresist 302 is 1 μm to 2 μm. The thickness T2 of the photoresist 302 may be greater than the thickness T1 of the sacrifice layer 301.

In some embodiments, the opening 312 of the photoresist 302 has a sloped wall. The width of the opening 312 may decrease in a direction away from the substrate 100. A minimum width W1 of the opening 313 of the sacrifice layer 301 may be greater than a minimum width W2 of the opening 312 of the photoresist 302. In some embodiments, the minimum width W2 of the opening 312 of the photoresist 302 is 3 μm to 9 μm.

In some embodiments, the opening 313 of the sacrifice layer 301 and the opening 312 of the photoresist 302 form a T-shaped structure and sizes thereof affect an evaporation range of an organic light emitting layer, and so the sizes and thicknesses of the sacrificial layer 301 and the photoresist 302 need to be especially designed so as to satisfy a predetermined evaporation range.

In some embodiments, the protrusions 310 are located on two sides of the first electrode 215 and have a spacing S1, which ranges between 3 μm and 9 μm. The spacing S1 of the protrusions 310 corresponds to a size of pixels (a light emitting region, that is, a region by which an organic light emitting layer covers electrodes). The width W2 of the opening 312 of the photoresist 302 may be greater than the spacing S1 of the protrusions 310. In some embodiments, a difference between the width W2 of the opening 312 of the photoresist 302 and the spacing S1 of the protrusions 310 is greater than or equal to 1 μm. From the perspective of a cross-sectional diagram, two ends of the opening 312 of the photoresist 302 may be spaced by different distances from two ends of pixels (a region between two protrusions 310), that is, the opening may not be precisely located directly above but may be a little shifted to the left or right. In other words, two sides of a light emitting region may be spaced by different distances from edges of an opening.

Since an incident angle of evaporation is restricted by an opening of a photoresist such that the width W2 (in combination with an angle of evaporation) of the opening 312 of the photoresist 302 is greater than the spacing S1 (the size of pixels) of the protrusions 310 and the difference is greater than or equal to 1 μm, coating onto the pixels (a light emitting region) can be achieved regardless of the angle of evaporation, while the thickness of the coating can stay uniform. When the thickness of an organic light emitting layer is uniform, uniform brightness is also achieved as lengths of paths traveled by electrons/holes are substantially the same. If the width W2 (in combination with an angle of evaporation) of the opening 312 of the photoresist 302 is less than the spacing S1 (the size of pixels) of the protrusions 310 or the difference is less than 1 μm, the thickness of the coating may not be uniform, for example, edges are thinner than the center. Due to higher brightness of thin regions, circles of light may be resulted to lead to non-uniform brightness.

In some embodiments, an incident angle θ1 of evaporation is 40° to 90 °, and an inclination angle θ2 of the sidewall of the photoresist 302 is 50° to 90°. Two sidewalls of the photoresist 302 may have different inclination angles.

Moreover, the sacrifice layer 301 has an undercut to provide a complete evaporation range, and at the same time it is also ensured that an organic light emitting layer is not coated onto a curved sidewall of the undercut of the sacrifice layer. The undercut may be located directly above the protrusion 310. In some embodiments, the undercut is located outside the top of a protrusion. In some embodiments, depths D1 and D1’ of the undercut of the opening 313 of the sacrifice layer 301 are 0.5 μm to 2 μm, and the two depths D1 and D1’ may be different from each other. Heights of the undercut may also be different. For example, the undercut may remove a portion of the sacrifice layer 301, or may remove a portion of each of the photoresist 302 and the sacrifice layer 301.

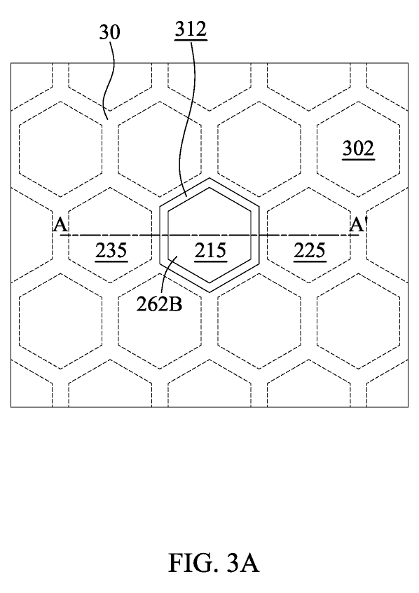

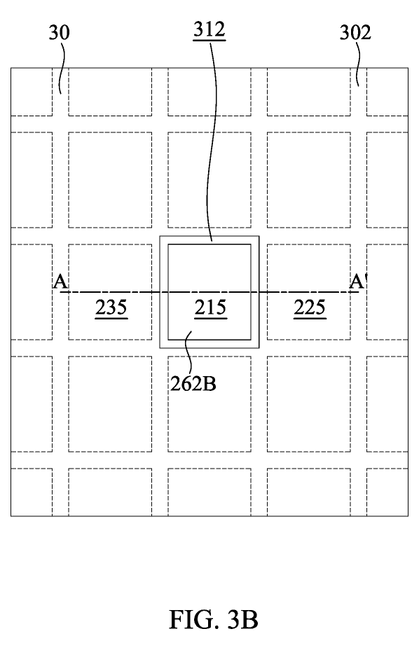

FIG. 3A and FIG. 3B show top views of an intermediate structure of a manufacturing method of the organic light emitting element 10A according to some embodiments. FIG. 2 shows a cross-sectional diagram taken along the line A-A’ in FIG. 3A and FIG. 3B. As shown in FIG. 2, FIG. 3A and FIG. 3B, the photoresist 302 covers the electrodes 225 and 235, and the opening 312 exposes the hole transport layer 262B over the electrode 215.

The opening 312 is shaped to correspond to a shape of pixels (a light emitting region). The pixels may be hexagonal, as shown in FIG. 3A. The pixels may be quadrilateral, as shown in FIG. 3B. However, the present application is not limited to the examples above, and the pixels may also be in other shapes.

Next, as shown in FIG. 1C, in some embodiments, the organic emissive layer 264a, the electron transport layer 265a and the electron injection layer 266a are sequentially arranged over the hole transport layer 262B over the electrode 215. In some embodiments, the organic emissive layer 264a, the electron transport layer 265a and the electron injection layer 266a are formed by means of evaporation.

In some embodiments, a total thickness T3 of the organic emissive layer 264a, the electron transport layer 265a and the electron injection layer 266a is 200 Å to 1300 Å.

Since the opening 313 of the sacrifice layer 301 has an undercut, portions of the organic emissive layer 264a, the electron transport layer 265a and the electron injection layer 266a extend above the protrusions 310. In some embodiments, the thickness of the organic emissive layer 264a, the electron transport layer 265a and the electron injection layer 266a above the protrusions 310 is less than that between the protrusions 310.

Next, in some embodiments, the sacrifice layer 301, the photoresist 302, and portions of the organic emissive layer 264a, the electron transport layer 265a and the electron injection layer 266a above the photoresist 302 are removed. Next, in some embodiments, the sacrifice layer 301, the photoresist 302, and the portions of the organic emissive layer 264a, the electron transport layer 265a and the electron injection layer 266a are removed by means of a wet etching process.

Next, refer to FIG. 1D. FIG. 1D shows an enlarged view of the region 1D (FIG. 1A). The steps in FIG. 1B and FIG. 1C are repeated. In some embodiments, the sacrifice layer 301 and the photoresist 302 are arranged over the protrusions 310, wherein the sacrifice layer 301 and the photoresist 302 cover the inorganic barrier layer 268, the hole injection layer 261A, the hole injection layer 261B, the hole transport layer 262A, the hole transport layer 262B, the organic emissive layer 264a, the electron transport layer 265a, the electron injection layer 266a, and the electrodes 215, 225 and 235. Next, an opening 314 is formed in the photoresist 302 and an opening 315 is formed in the sacrifice layer 301 by means of etching. The openings 314 and 315 are located directly above the electrode 225, and expose the hole transport layer 262B over the electrode 225.

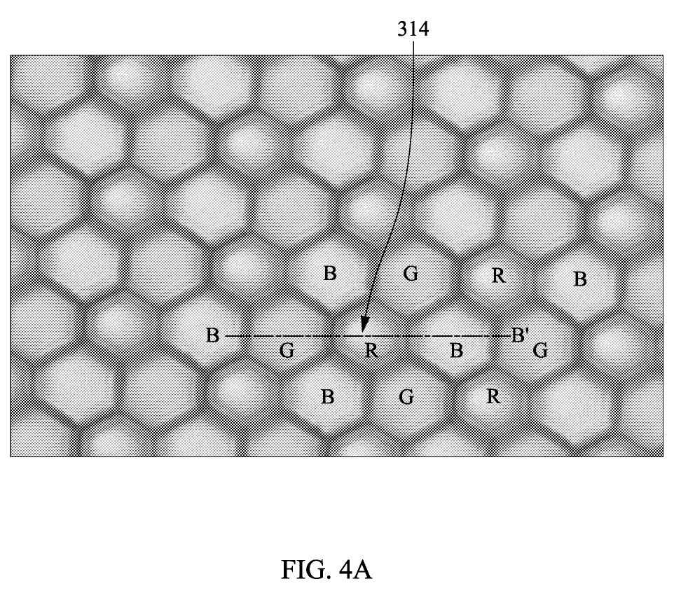

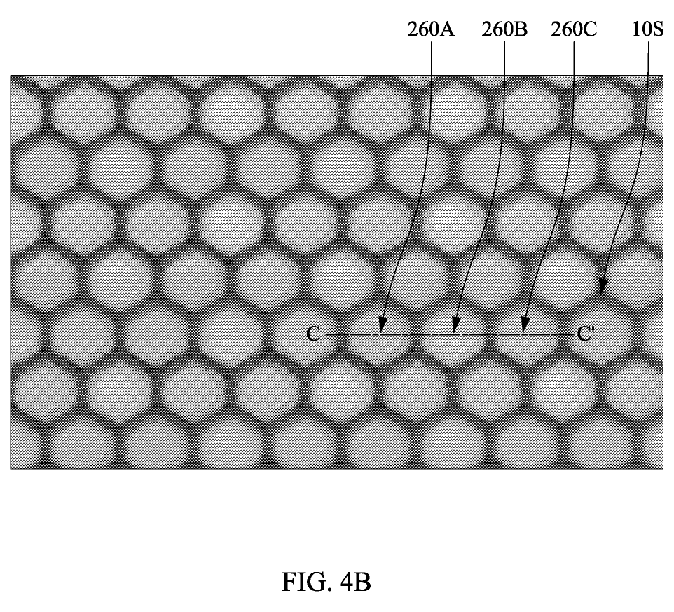

FIG. 1D shows a cross-sectional diagram taken along the line B-B’ in FIG. 4A. FIG. 4A shows a top view of an intermediate structure of a manufacturing method of the organic light emitting element 10A according to some embodiments. In some embodiments, as shown in FIG. 1D and FIG. 4A, predetermined evaporation positions of an organic emissive layer 264b, a hole blocking layer (HBL) 267, an electron transport layer 265b and an electron injection layer 266b (as shown in FIG. 1E) are defined by the opening 314 of the photoresist 302 at this point in time. Sizes of the sacrifice layer 301 and the photoresist 302 and a value of the incident angle of evaporation may be similar to those described with reference to FIG. 2, and shapes of the opening 314 and the pixels may also be similar to those described with reference to FIG. 3A and FIG. 3B; these repeated details are thus omitted herein.

Next, as shown in FIG. 1E, in some embodiments, the organic emissive layer 264b, the hole blocking layer 267, the electron transport layer 265b and the electron injection layer 266b are sequentially arranged over the hole transport layer 262B over the electrode 225. In some embodiments, the organic emissive layer 264b, the hole blocking layer 267, the electron transport layer 265b and the electron injection layer 266b are formed by means of evaporation.

Since the opening 315 of the sacrifice layer 301 has an undercut, portions of the organic emissive layer 264b, the hole blocking layer 267, the electron transport layer 265b and the electron injection layer 266b extend above the protrusions 310. In some embodiments, the thickness of the organic emissive layer 264b, the hole blocking layer 267, the electron transport layer 265b and the electron injection layer 266b above the protrusions 310 is less than that between the protrusions 310.

Since the organic emissive layer 264a, the electron transport layer 265a and the electron injection layer 266a extend above the protrusions 310, the organic emissive layer 264b, the hole blocking layer 267, the electron transport layer 265b and the electron injection layer 266b above the protrusions 310 cover the organic emissive layer 264a, the electron transport layer 265a and the electron injection layer 266a. In other words, the organic emissive layer 264b, the hole blocking layer 267, the electron transport layer 265b and the electron injection layer 266b vertically overlap the organic emissive layer 264a, the electron transport layer 265a and the electron injection layer 266a above the top of the protrusion 310.

Next, in some embodiments, the sacrifice layer 301, the photoresist 302, and portions of the organic emissive layer 264b, the hole blocking layer 267, the electron transport layer 265b and the electron injection layer 266b above the photoresist 302 are removed.

Next, refer to FIG. 1F. FIG. 1F shows an enlarged view of the region 1F (FIG. 1A). The steps in FIG. 1B and FIG. 1C or FIG. 1C and 1D are repeated. In some embodiments, the sacrifice layer 301 and the photoresist 302 are arranged over the protrusions 310, wherein the sacrifice layer 301 and the photoresist 302 cover the inorganic barrier layer 268, the hole injection layer 261A, the hole injection layer 261B, the hole transport layer 262A, the hole transport layer 262B, the organic emissive layer 264a, the electron transport layer 265a, the electron injection layer 266a, the organic emissive layer 264b, the hole blocking layer 267, the electron transport layer 265b, the electron injection layer 266b, and the electrodes 215, 225 and 235.

Next, an opening 316 is formed in the photoresist 302 and an opening 317 is formed in the sacrifice layer 301 by means of etching. The openings 316 and 317 are located directly above the electrode 235, and expose the hole transport layer 262B over the electrode 235. Sizes of the sacrifice layer 301 and the photoresist 302 and a value of the incident angle of evaporation may be similar to those described with reference to FIG. 2, and shapes of the opening 316 and the pixels may also be similar to those described with reference to FIG. 3A and FIG. 3B; these repeated details are thus omitted herein.

Next, as shown in FIG. 1G, in some embodiments, an organic emissive layer 264c, an electron transport layer 265c and an electron injection layer 266c are sequentially arranged over the hole transport layer 262B over the electrode 235. In some embodiments, the organic emissive layer 264c, the electron transport layer 265c and the electron injection layer 266c are formed by means of evaporation.

Since the opening 317 of the sacrifice layer 301 has an undercut, portions of the organic emissive layer 264c, the electron transport layer 265c and the electron injection layer 266c extend above the protrusions 310. In some embodiments, the thickness of the organic emissive layer 264c, the electron transport layer 265c and the electron injection layer 266c above the protrusions 310 is less than that between the protrusions 310.

Since the organic emissive layer 264a, the electron transport layer 265a and the electron injection layer 266a extend above a protrusion 310, the organic emissive layer 264c, the electron transport layer 265c and the electron injection layer 266c above this protrusion 310 cover the organic emissive layer 264a, the electron transport layer 265a and the electron injection layer 266a. Similarly, since the organic emissive layer 264b, the hole blocking layer 267, the electron transport layer 265b and the electron injection layer 266b extend above another protrusion 310, the organic emissive layer 264c, the electron transport layer 265c and the electron injection layer 266c above this protrusion 310 cover the organic emissive layer 264b, the hole blocking layer 267, the electron transport layer 265b and the electron injection layer 266b. In other words, the organic emissive layer 264c, the electron transport layer 265c and the electron injection layer 266c vertically overlap the organic emissive layer 264a, the electron transport layer 265a and the electron injection layer 266a above the top of one protrusion 310, and the organic emissive layer 264c, the electron transport layer 265c and the electron injection layer 266c vertically overlap the organic emissive layer 264b, the hole blocking layer 267, the electron transport layer 265b and the electron injection layer 266b above the top of the another protrusion 310.

Next, refer to FIG. 1H. FIG. 1H shows an enlarged view of the region 1B (FIG. 1A). In some embodiments, the sacrifice layer 301, the photoresist 302, and portions of the organic emissive layer 264c, the electron transport layer 265c and the electron injection layer 266c above the photoresist 302 are removed. Up to this point, organic light emitting layers 260A, 260B and 260C (or a light emitting layer 20) are formed. In some embodiments, the light emitting layer 20 includes the organic light emitting layer 260A (or referred to as a first organic light emitting layer), the organic light emitting layer 260B (or referred to as a second organic light emitting layer) and the organic light emitting layer 260C (or referred to as a third organic light emitting layer).

In some embodiments, the organic light emitting layer 260A includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264a, the electron transport layer (ETL) 265a and the electron injection layer (EIL) 266a.

In some embodiments, the organic light emitting layer 260B includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264b, the hole blocking layer (HBL) 267, the electron transport layer (ETL) 265b and the electron injection layer (EIL) 266b.

In some embodiments, the organic light emitting layer 260C includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264c, the electron transport layer (ETL) 265c and the electron injection layer (EIL) 266c.

In some embodiments, the organic light emitting layer 260A is located over the electrode 215, the organic light emitting layer 260B is located over the electrode 225, and the organic light emitting layer 260C is located over the electrode 235. In some embodiments, a thickness of the organic light emitting layer 260A, a thickness of the organic light emitting layer 260B and a thickness of the organic light emitting layer 260C are different from one another. In some embodiments, the thickness of the organic light emitting layer 260B is greater than the thickness of the organic light emitting layer 260A, and the thickness of the organic light emitting layer 260A is greater than the thickness of the organic light emitting layer 260C.

In some embodiments, the organic light emitting layers 260A, 260B and 260C emit light having the same color or different colors. In some embodiments, a luminescence wavelength of the organic light emitting layer 260B is greater than a luminescence wavelength of the organic light emitting layer 260A, and the luminescence wavelength of the organic light emitting layer 260A is greater than a luminescence wavelength of the organic light emitting layer 260C. In some embodiments, the organic light emitting layer 260A emits green light, the organic light emitting layer 260B emits red light, and the organic light emitting layer 260C emits blue light.

In some embodiments, the organic material layers of the organic light emitting layers 260A, 260B and 260C include an organic material, which may be placed in any of the organic material layers of the organic light emitting layers 260A, 260B and 260C according to different embodiments. In some embodiments, the organic material has an absorption rate of greater than or equal to 50% for a specific wavelength. In some embodiments, the organic material has an absorption rate of greater than or equal to 60% for a specific wavelength. In some embodiments, the organic material has an absorption rate of greater than or equal to 70% for a specific wavelength. In some embodiments, the organic material has an absorption rate of greater than or equal to 80% for a specific wavelength. In some embodiments, the organic material has an absorption rate of greater than or equal to 90% for a specific wavelength. In some embodiments, the organic material has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the inorganic barrier layer 268 is located between the electrodes 215, 225 and 235 and the organic light emitting layers 260A, 260B and 260C. In some embodiments, the inorganic barrier layer 268 substantially completely covers interfaces between the electrodes 215, 225 and 235 and the organic light emitting layers 260A, 260B and 260C.

In some embodiments, FIG. 1H is a cross-sectional diagram taken along the line C-C’ in FIG. 4B. FIG. 4B shows a top view of an intermediate structure of a manufacturing method of the organic light emitting element 10A according to some embodiments. As shown in FIG. 4B, at this point in time, the electron injection layer 266a of the organic light emitting layer 260A is already formed above the electrode 215 by means of evaporation, the electron injection layer 266b of the organic light emitting layer 260B is already formed above the electrode 225 by means of evaporation, and the electron injection layer 266c of the organic light emitting layer 260C is already formed above the electrode 235 by means of evaporation. As shown in FIG. 4B, the organic light emitting layers 260A, 260B and 260C overlap vertically at borders of pixels, and have an overlapping region 10S. In some embodiments, a with of the overlapping region 10S is less than 1 μm. In some embodiments, the width of the overlapping region 10S is non-uniform.

As shown in FIG. 1I, an electrode 216 is arranged over the organic light emitting layers 260A, 260B and 260C and the spacer structure 30. Up to this point, organic light emitting units (or referred to as light emitting pixels) 101, 102 and 103 are formed. The organic light emitting unit 101 (or referred to as a first organic light emitting unit) includes the electrode 215, the organic light emitting layer 260A and the electrode 216, the organic light emitting unit 102 (or referred to as a second organic light emitting unit) includes the electrode 225, the organic light emitting layer 260B and the electrode 216, and the organic light emitting unit 103 (or referred to as a third organic light emitting unit) includes the electrode 235, the organic light emitting layer 260C and the electrode 216. The organic light emitting units 101, 102 and 103 may emit light having the same wavelength or light having different wavelengths. In some embodiments, the organic light emitting units 101, 102 and 103 are between the protrusions 310 and above the substrate 100.

More specifically, the electrode 216 may be located above the electron injection layers 266a, 266b and 266c. In some embodiments, the electrode 216 is in contact with the organic light emitting layers 260A, 260B and 260C. The electrode 216 may be a continuous film as shown in FIG. 1I and be located over the organic light emitting layers 260A, 260B and 260C and the protrusions 310. In some embodiments, the electrode 216 may be further located over the spacer structure 30. In some embodiments, the electrode 216 is a common electrode of all light emitting pixels in the light emitting layer 20. In some embodiments, the electrode 216 includes a metal material, for example, Ag, Al, Mg, Au, AlCu alloy or AgMo alloy. In some embodiments, the electrode 216 includes ITO, IZO or other appropriate materials. In other words, the electrode 216 is a common electrode of a plurality of organic light emitting units. In some embodiments, the electrode 216 is a common electrode of all organic light emitting units in the organic light emitting element 10A.

In some embodiments, the surface 2151 of the electrode 215 faces the electrode 216, and the surface 2152 opposite to the surface 2151 of the electrode 215 faces the substrate 100 and is in contact with the reflective layer 281. In some embodiments, the reflective layer 281 includes the reflective surface 281a (or referred to as a first reflective surface), and the electrode 216 includes a surface 2162 (or referred to as a second reflective surface), wherein the reflective surface 281a and the surface 2162 face the organic light emitting layer 260A. In some embodiments, the electrode 215 is a transparent electrode, and the reflective surface 281a is for further reflecting light emitted by the organic light emitting layer 260A. In some embodiments, the reflective surface 281a back faces a light exiting surface (for example, a surface 100b) of the organic light emitting element 10A, and the reflective surface 281a is closer to the light exiting surface of the organic light emitting element 10A than the surface 2162. In some embodiments, for the light emitted by the organic light emitting layer 260A, the reflectance of the reflective surface 281a is greater than or equal to 30%, for example, greater than or equal to 40%, greater than or equal to 50%, greater than or equal to 60%, or greater than or equal to 70%. In some embodiments, for the light emitted by the organic light emitting layer 260A, the reflectance of the surface 2162 (or the second reflective surface) is greater than the reflectance of the reflective surface 281a (or the first reflective surface), for example, greater than or equal to 80%, greater than or equal to 85%, greater than or equal to 90%, or greater than or equal to 95%.

In some embodiments, the surface 2251 of the electrode 225 faces the electrode 216, and the surface 2252 opposite to the surface 2251 of the electrode 225 faces the substrate 100 and is in contact with the reflective layer 282. In some embodiments, the reflective layer 282 includes the reflective surface 282a (or referred to as a third reflective surface), which faces the organic light emitting layer 260B. In some embodiments, the electrode 225 is a transparent electrode, and the reflective surface 282a is for further reflecting the light emitted by the organic light emitting layer 260B. In some embodiments, the reflective surface 282a back faces the light exiting surface of the organic light emitting element 10A, and the reflective surface 282a is closer to the light exiting surface of the organic light emitting element 10A than the surface 2162. In some embodiments, for the light emitted by the organic light emitting layer 260B, the reflectance of the reflective surface 282a is greater than or equal to 30%, for example, greater than or equal to 40%, greater than or equal to 50%, greater than or equal to 60%, or greater than or equal to 70%. In some embodiments, for the light emitted by the organic light emitting layer 260B, the reflectance of the surface 2162 (or referred to as the second reflective surface) is greater than the reflectance of the reflective surface 282a (or the first reflective surface), for example, greater than or equal to 80%, greater than or equal to 85%, greater than or equal to 90%, or greater than or equal to 95%.

In some embodiments, the surface 2351 of the electrode 235 faces the electrode 216, and the surface 2352 opposite to the surface 2351 of the electrode 235 faces the substrate 100 and is in contact with the reflective layer 283. In some embodiments, the reflective layer 283 includes the reflective surface 283a (or referred to as a fourth reflective surface), which faces the organic light emitting layer 260C. In some embodiments, the electrode 235 is a transparent electrode, and the reflective surface 283a is for further reflecting the light emitted by the organic light emitting layer 260C. In some embodiments, the reflective surface 283a back faces the light exiting surface of the organic light emitting element 10A, and the reflective surface 283a is closer to the light exiting surface of the organic light emitting element 10A than the surface 2162. In some embodiments, for the light emitted by the organic light emitting layer 260C, the reflectance of the reflective surface 283a is greater than or equal to 30%, for example, greater than or equal to 40%, greater than or equal to 50%, greater than or equal to 60%, or greater than or equal to 70%. In some embodiments, for the light emitted by the organic light emitting layer 260C, the reflectance of the surface 2162 (or the second reflective surface) is greater than the reflectance of the reflective surface 283a (or the first reflective surface), for example, greater than or equal to 80%, greater than or equal to 85%, greater than or equal to 90%, or greater than or equal to 95%.

In some embodiments, when the reflectance of a reflective surface (or the first reflective surface) is greater than or equal to 30%, the full width at half maximum (FWHM) of the luminescence peak spectrum of an organic light emitting layer may be reduced by greater than or equal to 10%. In some embodiments, when the reflectance of a reflective surface (or the first reflective surface) is greater than or equal to 40%, the full width at half maximum (FWHM) of the luminescence peak spectrum of an organic light emitting layer may be reduced by greater than or equal to 15%. In some embodiments, when the reflectance of a reflective surface (or the first reflective surface) is greater than or equal to 50%, the full width at half maximum (FWHM) of the luminescence peak spectrum of an organic light emitting layer may be reduced by greater than or equal to 20%. In some embodiments, when the reflectance of a reflective surface (or the first reflective surface) is greater than or equal to 60%, the full width at half maximum (FWHM) of the luminescence peak spectrum of an organic light emitting layer may be reduced by greater than or equal to 25%.

In some embodiments, when the reflectance of a reflective surface (or the first reflective surface) is greater than or equal 30%, the light diffusion angle of an organic light emitting layer is approximately less than or equal to positive/negative 60°. In some embodiments, when the reflectance of a reflective surface (or the first reflective surface) is greater than or equal to 40%, the light diffusion angle of an organic light emitting layer is approximately less than or equal to positive/negative 50 °. In some embodiments, when the reflectance of a reflective surface (or the first reflective surface) is greater than or equal to 50%, the light diffusion angle of an organic light emitting layer is approximately less than or equal to positive/negative 40 °. In some embodiments, when the reflectance of a reflective surface (or the first reflective surface) is greater than or equal to 60%, the light diffusion angle of an organic light emitting layer is approximately less than or equal to positive/negative 30 °.

Next, in some embodiments, an inorganic barrier layer 270 is arranged over the electrode 216. In some embodiments, the inorganic barrier layer 270 includes a transition metal oxide. In some embodiments, the inorganic barrier layer 270 includes molybdenum oxide (MoO3). In some embodiments, a thickness of the inorganic barrier layer 270 is less than or equal to 100 Å. In some embodiments, a ratio of the thickness of the inorganic barrier layer 270 to the thickness of the electrode 216 is less than 0.15, 0.1 or 0.05.

Next, as shown in FIG. 1J, in some embodiments, a cover layer 40 is arranged over the inorganic barrier layer 270. The cover layer 40 includes a capping layer 410, an encapsulation layer 420, a filler layer 430 and a cover plate 440. In some embodiments, the capping layer 410 is formed by means of evaporation. In some embodiments, the capping layer 410 is arranged over the electrode 216, and is substantially conformal with a non-flat upper surface of the electrode 216. The capping layer 410 may include a dielectric material or an inorganic insulating material, for example, SiO₂. In some embodiments, the capping layer 410 may include a hole transport layer material to extract light lost inside the organic light emitting element so as to improve light emitting efficiency. The capping layer 410 may also be referred to as a light extraction layer.

In some embodiments, the inorganic barrier layer 270 is in contact with the capping layer 410. In some embodiments, the capping layer 410 is located over the inorganic barrier layer 270, and is separated from the electrode 216 by the inorganic barrier layer 270. In some embodiments, the inorganic barrier layer 270 substantially completely covers an interface between the electrode 216 and the capping layer 410. In some embodiments, a ratio of the thickness of the inorganic barrier layer 270 to the thickness of the capping layer 410 is less than 0.5, 0.3 or 0.15.

The encapsulation layer 420 is arranged over the capping layer 410. In some embodiments, the encapsulation layer 420 is formed by means of plasma-enhanced chemical vapor deposition (PECVD). In some embodiments, the encapsulation layer 420 is arranged over the capping layer 410, and is substantially conformal with a non-flat upper surface of the capping layer 410. The encapsulation layer 420 may include an oxide, for example, SiO₂. In some embodiments, the encapsulation layer 420 is substantially conformal with the non-flat upper surface of the capping layer 410, and includes a plurality of recesses corresponding to the organic light emitting layers 260A, 260B and 260C. The encapsulation layer 420 may include a polymer organic material, for example, an epoxy-based material.

In some embodiments, the filler layer 430 is arranged over the encapsulation layer 420, and a lower surface of the filler layer 430 is substantially conformal with a non-flat upper surface of the encapsulation layer 420. The filler layer 430 may also be referred to as a flat layer. The filler layer 430 may include a polymer organic material, for example, an epoxy-based material.

In some embodiments, the cover plate 440 is arranged over a flat upper surface of the filler layer 430. The cover plate 440 may also be referred to as a protective layer. The cover plate 440 may include a transparent hard cover plate, for example, a glass plate. The cover plate 440 may be used to prevent components of the organic light emitting element from coming into contact with external moisture and hence from malfunction and light emission failures of the components.

Up to this point, the organic light emitting element 10A is formed. More specifically, the organic light emitting element 10A includes the substrate 100, the electrode 215, the electrode 225, the electrode 235, the electrode 216, the light emitting layer 20, the inorganic barrier layer 268, the inorganic barrier layer 270, the reflective layer 281, the reflective layer 282, the reflective layer 283, the spacer structure 30 and the cover layer 40.

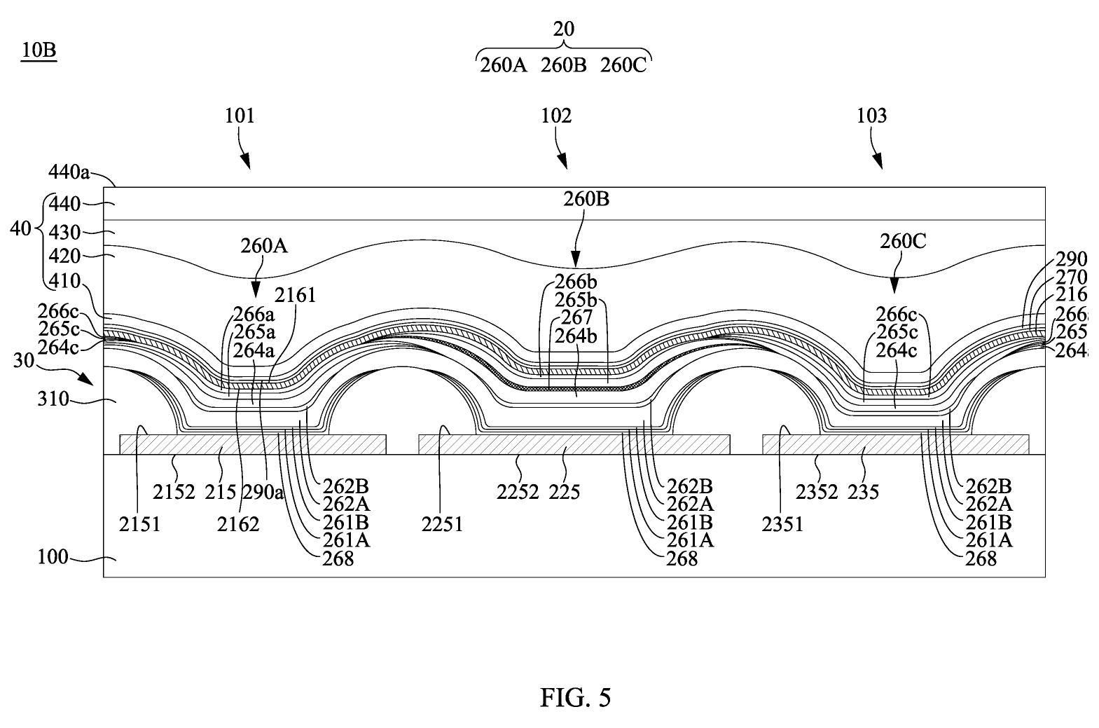

FIG. 5 shows a cross-sectional diagram of an organic light emitting element 10B. The structure in FIG. 5 is similar to the structure in FIG. 1J, and differences thereof are described below.

In some embodiments, the organic light emitting element 10B includes a reflective layer 290, the electrode 216 is a transparent electrode, and the reflective layer 290 is located between the capping layer 410 and the electrode 216. In some embodiments, the reflective layer 290 includes a non-conductive material, for example, a distributed Bragg reflector (DBR). In some embodiments, the reflective layer 290 includes a plurality of pairs of non-conductive material layers, and a difference between the reflectances of each pair of the non-conductive material layers is greater than or equal to 0.4. In some embodiments, the reflective layer 290 includes a reflective surface 290a. In some embodiments, the surface 2161 of the electrode 216 faces the capping layer 410. In some embodiments, the surface 2162 of the electrode 216 faces the electrodes 215, 225 and 235. In some embodiments, for the light emitted by the organic light emitting layers 260A, 260B and 260C, the reflectance of the reflective surface 290a is greater than or equal to 30%, for example, greater than or equal to 40%, greater than or equal to 50%, greater than or equal to 60%, or greater than or equal to 70%. In some embodiments, a light exiting surface of the organic light emitting element 10B is a surface 440a of the cover plate 440.

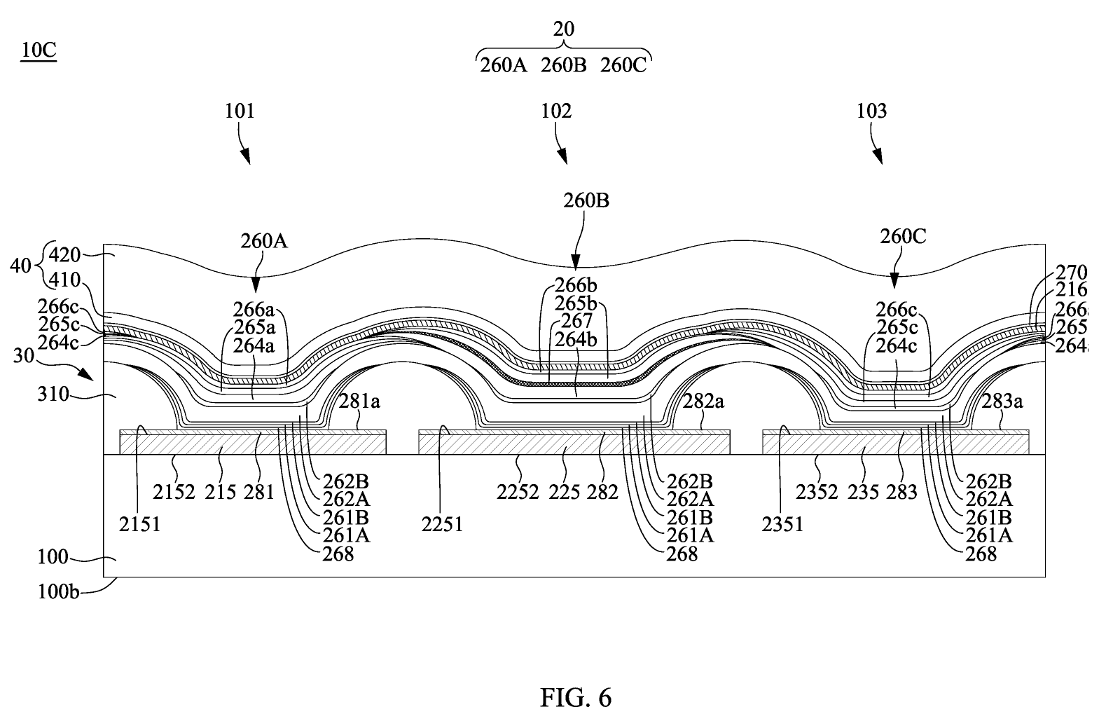

FIG. 6 shows a cross-sectional diagram of an organic light emitting element 10C. The structure in FIG. 6 is similar to the structure in FIG. 1J, and differences thereof are described below.

In some embodiments, the organic light emitting element 10C includes the reflective layers 281, 282 and 283, which are located between the organic light emitting layers 260A, 260B and 260C and the electrodes 215, 225 and 235. In some embodiments, the reflective layers 281, 282 and 283 include the reflective surfaces 281a, 282a and 283a. In other words, reflective surfaces (the reflective surfaces 281a, 282a and 283a of the reflective layers 281, 282 and 283) are formed on upper surfaces (the surfaces 2151, 2251 and 2351) of the electrodes 215, 225 and 235.

In some embodiments, for the light emitted by the organic light emitting layers 260A, 260B and 260C, the reflectances of the reflective surfaces 281a, 282a and 283a are greater than or equal to 30%, for example, greater than or equal to 40%, greater than or equal to 50%, greater than or equal to 60%, or greater than or equal to 70%. In some embodiments, a light exiting surface of the organic light emitting element 10C is the surface 100b of the substrate 100.

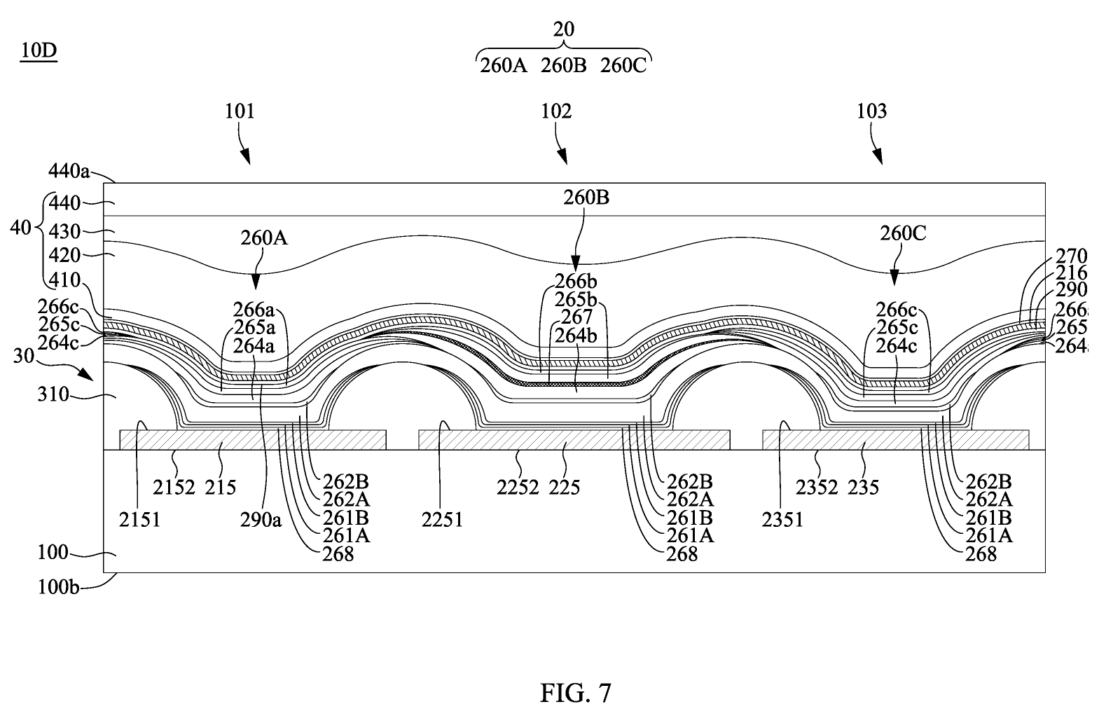

FIG. 7 shows a cross-sectional diagram of an organic light emitting element 10D. The structure in FIG. 7 is similar to the structure in FIG. 1J, and differences thereof are described below.

In some embodiments, the organic light emitting element 10D includes the reflective layer 290, which is further located between the organic light emitting layers 260A, 260B and 260C and the electrode 216. In some embodiments, the reflective layer 290 includes a reflective surface 290a. In some embodiments, for the light emitted by the organic light emitting layers 260A, 260B and 260C, the reflectance of the reflective surface 290a is greater than or equal to 30%, for example, greater than or equal to 40%, greater than or equal to 50%, greater than or equal to 60%, or greater than or equal to 70%. In some embodiments, a light exiting surface of the organic light emitting element 10D is the surface 440a of the cover plate 440.

The features of some embodiments are described briefly above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made to the embodiments by a person skilled in the art without departing from the spirit and scope of the present disclosure.

What is claimed is:

1. An organic light emitting element, comprising:
a substrate;
a first light emitting unit, located over the substrate, and comprising:
a first electrode; and
a first organic light emitting layer, located over the first electrode; and
a second organic light emitting unit, adjacent to the first organic light emitting layer, and comprising:
a second electrode; and
a second organic light emitting layer, located over the second electrode,
wherein the first organic light emitting layer and the second organic light emitting layer overlap vertically.

2. The organic light emitting element according to claim 1, further comprising:
a protrusion, located between the first organic light emitting unit and the second organic light emitting unit, wherein the first organic light emitting layer and the second organic light emitting layer extend over a top of the protrusion.

3. The organic light emitting element according to claim 2, wherein the first organic light emitting layer and the second organic light emitting layer overlap vertically over the top of the protrusion.

4. The organic light emitting element according to claim 2, wherein a thickness of the first organic light emitting layer on a sidewall of the protrusion is greater than a thickness of the first organic light emitting layer on the top of the protrusion.

5. The organic light emitting element according to claim 1, wherein the first organic light emitting unit and the second organic light emitting unit emit lights having different wavelengths.

6. The organic light emitting element according to claim 1, wherein the first organic light emitting layer comprises a first organic emissive layer, a first electron transport layer and a first electron injection layer, and the second organic light emitting layer comprises a second organic emissive layer, a second electron transport layer and a second electron injection layer, wherein the second organic emissive layer, the second electron transport layer and the second electron injection layer extend over the first organic emissive layer, the first electron transport layer and the first electron injection layer.

7. The organic light emitting element according to claim 1, wherein the first organic light emitting layer extends above a sidewall of the second electrode.

8. The organic light emitting element according to claim 1, further comprising:
a third organic light emitting unit, adjacent to the second organic light emitting layer, and comprising:
a third electrode; and
a third organic light emitting layer, located over the third electrode,
wherein the third organic light emitting layer and the second organic light emitting layer overlap vertically.

9. A manufacturing method of an organic light emitting element, comprising:
disposing a first electrode over a substrate;
forming a plurality of protrusions having a spacing and on two sides of the first electrode;
sequentially forming a sacrifice layer and a photoresist over the first electrode;
forming an opening passing through the sacrifice layer and the photoresist directly above the first electrode, wherein the opening in the sacrifice layer has a first width and in the photoresist has a second width, the first width is greater than the second width, and the second width is greater than the spacing;
forming a first organic light emitting layer over the first electrode; and
removing the sacrifice layer and the photoresist.

10. The manufacturing method according to claim 9, wherein the opening in the sacrifice layer has an undercut located directly above the protrusion.

11. The manufacturing method according to claim 10, wherein a depth of the undercut is 0.5 μm to 2 μm.

12. The manufacturing method according to claim 9, wherein a difference between the second width and the spacing is greater than or equal to 1 μm.

13. The manufacturing method according to claim 9, wherein the second width is 4 μm to 10 μm, and the spacing is 3 μm to 9 μm.

14. The manufacturing method according to claim 9, wherein after the forming of the opening, an inclination angle of the photoresist is 50° to 90°.

15. The manufacturing method according to claim 9, wherein the first organic light emitting layer is formed by evaporation, and an incident angle of the evaporation is 40° to 90°.

16. The manufacturing method according to claim 9, wherein a thickness of the sacrifice layer is 0.5 μm to 1 μm, a thickness of the photoresist is 1 μm to 2 μm, and a thickness of the first organic light emitting layer is 200 Å to 1300 Å.

17. The manufacturing method according to claim 9, further comprising:
disposing a second electrode adjacent to the first electrode, wherein the sacrifice layer and the photoresist cover the second electrode while forming the first organic light emitting layer; and
after the removing of the sacrifice layer and the photoresist, forming a second organic light emitting layer over the second electrode, the protrusion and the first organic light emitting layer.

18. The manufacturing method according to claim 9, wherein the opening has a T-shaped structure.

19. The manufacturing method according to claim 9, wherein the opening has an arc-shaped sidewall in the sacrifice layer and a sloped sidewall in the photoresist.

20. The manufacturing method according to claim 9, wherein the spacing defines a light emitting region of the first organic light emitting layer, and two sides of the light emitting region are separated by different distances from edges of the opening.
